(19) United States
(12) Patent Application Publication
(10) Pub. No.: US 2026/0236127 A1
(43) Pub. Date: Aug. 13, 2026

(54) INPUT SENSING PART, DISPLAY DEVICE INCLUDING INPUT SENSING PART, AND ELECTRONIC DEVICE INCLUDING DISPLAY DEVICE

(71) Applicant: Samsung Display Co., LTD., Yongin-si (KR)

(72) Inventors: JUNGHA SON, Yongin-si (KR); JUNGHAK KIM, Yongin-si (KR); YUN A MA, Yongin-si (KR); SANGWOOK YOO, Yongin-si (KR); JEONGHEON LEE, Yongin-si (KR)

(21) Appl. No.: 19/385,452

(22) Filed: Nov. 11, 2025

(30) Foreign Application Priority Data
Feb. 11, 2025 (KR) 10-2025-0017021

(51) Int. Cl. G06F 3/044; G06F 3/041; H10K 59/40

(52) U.S. Cl. CPC G06F 3/0446; G06F 3/04164; H10K 59/40; G06F 2203/04112

(57) ABSTRACT

An input sensing part includes a first sensing electrode disposed in an active area, and extending in a first direction, a sensing electrode disposed in the active area, extending in a second direction crossing the first direction, and crossing the first sensing electrode while being insulated from the first sensing electrode, a guard line disposed in a non-active area to be adjacent to an upper side of the active area when viewed on a plane, and a connection line disposed in a non-active area to be adjacent to a lower side of the active area when viewed on the plane, extending toward the guard line via the active area, and connected to the guard line.

This application claims priority to Korean Patent Application No. 10-2025-0017021, filed on Feb. 11, 2025, and all the benefits accruing therefrom under 35 U.S.C. § 119, the content of which in its entirety is herein incorporated by reference.

### BACKGROUND

### (1) Field

Embodiments of the present disclosure described herein relate to an input sensing part, a display device including the input sensing part, and an electronic device including the display device.

### (2) Description of the Related Art

Generally, electronic devices, which provide images to users, such as a smartphone, a digital camera, a laptop computer, a navigation system, and a smart television include a display device for displaying the images. The display device generates an image and provides the users with the generated image through a display screen.

The display device typically includes a display panel for generating an image, and an input sensing part that is disposed on a display panel to sense an external input. The input sensing part is disposed on the display panel to sense a touch of the user as an external input. The input sensing part includes a plurality of sensing electrodes for sensing the external input, and sensing lines that are connected to the sensing electrodes.

### SUMMARY

In a display device including a sensing unit, a driving signal may be applied to sensing electrodes, and a change in the capacitance of the sensing electrodes is output as a sensing signal. The driving signal may be applied to the sensing electrodes through sensing lines. When a driving signal having a specific frequency is applied to the sensing electrodes, electromagnetic waves according to the driving signal may be radiated as an undesired electromagnetic signal.

The electromagnetic signals may act as noise to other devices and may hinder the operations of other devices. This phenomenon may be defined as electromagnetic interferences (EMIs). Accordingly, it is desired to develop a technology that may reduce electromagnetic interferences.

Embodiments of the present disclosure provide an input sensing part that may prevent electromagnetic interferences, a display device including the input sensing part, and an electronic device including the display device.

According to an embodiment, an input sensing part includes a first sensing electrode disposed in an active area, and extending in a first direction, a sensing electrode disposed in the active area, extending in a second direction crossing the first direction, and crossing the first sensing electrode while being insulated from the first sensing electrode, a guard line disposed in a non-active area to be adjacent to an upper side of the active area when viewed on a plane, and a connection line disposed in a non-active area to be adjacent to a lower side of the active area when viewed on the plane, extending toward the guard line via the active area, and connected to the guard line.

According to an embodiment, a display device includes a display panel, and an input sensing part disposed on the display panel, the input sensing part includes a first sensing electrode disposed in an active area, and extending in a first direction, a sensing electrode disposed in the active area, extending in a second direction crossing the first direction, and crossing the first sensing electrode while being insulated from the first sensing electrode, a guard line disposed in a non-active area to be adjacent to an upper side of the active area when viewed on a plane, and a connection line disposed in a non-active area to be adjacent to a lower side of the active area when viewed on the plane, extending toward the guard line via the active area, and connected to the guard line, and the connection line is disposed in a layer different from a layer in which the guard line is disposed.

According to an embodiment, an electronic device includes a processor, and a display device which receives an image signal from the processor, and provides a user with an image corresponding to the image signal, where the display device includes a display panel, and an input sensing part disposed on the display panel. In such an embodiment, the input sensing part includes a first sensing electrode disposed in an active area, and extending in a first direction, a sensing electrode disposed in the active area, extending in a second direction crossing the first direction, and crossing the first sensing electrode while being insulated from the first sensing electrode, a guard line disposed in a non-active area to be adjacent to an upper side of the active area when viewed on a plane, and a connection line disposed in a non-active area to be adjacent to a lower side of the active area when viewed on the plane, extending toward the guard line via the active area, and connected to the guard line, and the connection line extends via an area between the first sensing electrode and the second sensing electrode in the active area.

### BRIEF DESCRIPTION OF THE DRAWINGS

The above and other features of embodiments of the present disclosure will become apparent by describing in detail embodiments thereof with reference to the accompanying drawings.

FIG. 1 is a block diagram of an electronic device according to an embodiment of the present disclosure.

FIG. 2 illustrates schematic views of an electronic device according to various embodiments.

FIG. 3 is a perspective view of a display device according to an embodiment of the present disclosure.

FIG. 4 is a view illustrating a cross section of the display device illustrated in FIG. 3, by way of example.

FIG. 5 is a view illustrating a cross section of a display panel illustrated in FIG. 4, by way of example.

FIG. 6 is a view illustrating a cross section of a display panel according to another embodiment of the present disclosure.

FIG. 7 is a plan view of a display panel illustrated in FIG. 4.

FIG. 8 is a diagram illustrating a cross section of one pixel illustrated in FIG. 7.

FIG. 9 is a plan view of an input sensing part illustrated in FIG. 4.

FIG. 10 is an enlarged view of area AA′ illustrated in FIG. 9.

FIG. 11 is an enlarged view of a first area AA1 illustrated in FIG. 10.

FIG. 12 is an enlarged view of a second area AA2 illustrated in FIG. 10.

FIG. 13 is a view separately illustrating a connection line and sensor connection lines that are disposed on the same layer in FIG. 12.

FIG. 14 is a view separately illustrating first sensing parts, dummy electrodes, and an extension pattern that are disposed on the same layer in FIG. 12.

FIG. 15 is a cross-sectional view of area BB illustrated in FIG. 12.

FIG. 16 is an enlarged view of a third area AA3 illustrated in FIG. 10.

FIG. 17 is an enlarged view of area CC illustrated in FIG. 9.

FIG. 18 is a cross-sectional view taken along line I-I′ illustrated in FIG. 17.

FIGS. 19A and 19B are views illustrating timings of a driving signal applied to first sensing electrodes illustrated in FIG. 9 and an offset signal applied to a connection line illustrated in FIG. 9, by way of example.

FIG. 20 is a view illustrating a sensing controller for applying a driving signal and an offset signal to first sensing electrodes and a connection line illustrated in FIG. 9, by way of example.

FIGS. 21 to 23 are views illustrating configurations of connection lines according to various embodiments of the present disclosure.

FIGS. 24 to 26 are views illustrating configurations of guard lines according to various embodiments of the present disclosure.

FIG. 27 is a cross-sectional view taken along line II-II′ illustrated in FIG. 26.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In the specification, the expression that a first component (or area, layer, part, portion, etc.) is “connected with”, or “coupled with” a second component means that the first component is directly connected with, or coupled with the second component or means that a third component is interposed therebetween.

The same reference numerals refer to the same components. Furthermore, in drawings, the thickness, ratio, and dimension of components are exaggerated for effectiveness of description of technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical terms and scientific terms) used in the specification have the same meaning as commonly understood by one skilled in the art to which the present disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to the accompanying drawings.

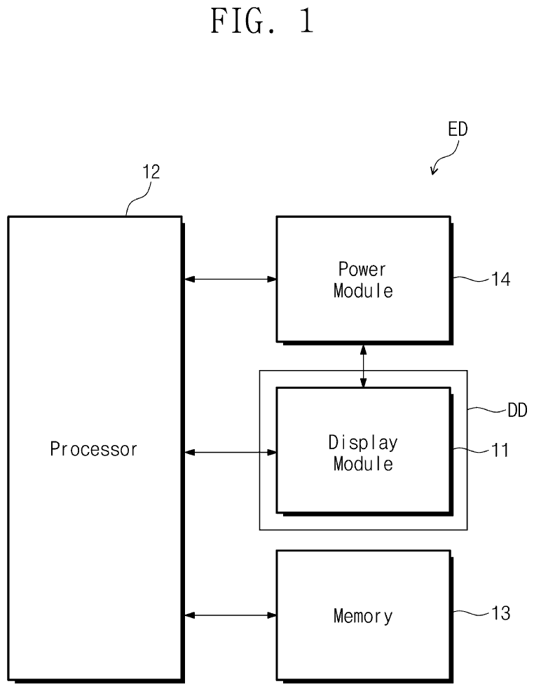

FIG. 1 is a block diagram of an electronic device according to an embodiment of the present disclosure.

Referring to FIG. 1, an electronic device ED according to an embodiment includes a display device DD that provides a user with an image, and may further include a module or a device having other additional functions in addition to the display device DD. The electronic device ED according to an embodiment may include a display module 11, a processor 12, a memory 13, and a power module 14, and the display device DD may include a display module 11.

The processor 12 may include at least one selected from a central processing unit (CPU), an application processor (AP), a graphic processing unit (GPU), a communication processor (CP), an image signal processor (ISP), and a controller.

The processor 12 may process an image signal and provide it to the display device DD. The display device DD may receive an image signal from the processor 12 and provide an image corresponding to the image signal to a user.

The processor 12 may be electrically connected to a display module 11 of the display device DD through a flexible circuit board and a connector. The display module 11 may display an image based on data received from the processor 12.

In an embodiment, the processor 12 may be divided into two or more parts from a functional or structural point of view to be provided. In an embodiment, for example, the processor 12 may include a main processor in the form of a first driving chip including a central processing unit, and an auxiliary processor in the form of a second driving chip including a controller that receives an image signal from the main processor and processes the image signal to meet interface specifications of the display module 11.

Data information that are used for an operation of the processor 12 or the display module 11 may be stored in the memory 13. When the processor 12 executes an application stored in the memory 13, an image signal and/or an input control signal may be transmitted to the display module 11, and the display module 11 may process the provided image signal and output image information through a display screen.

The power module 14 may include a power supply module, such as a power adapter or a battery device, and a power conversion module that converts electric power supplied by the power supply module to generate electric power that is required for an operation of the electronic device ED.

At least one of the components of the electronic device ED described above may be included in the display device DD according to the above-described embodiments. Furthermore, some of the individual modules that are functionally included in one module may be included in the display device DD, and others may be provided separately from the display device DD. In an embodiment, for example, the display device DD includes a display module 11, and the processor 12, the memory 13, and the power module 14 may be provided in the form of other devices in the electronic device ED rather than the display device DD.

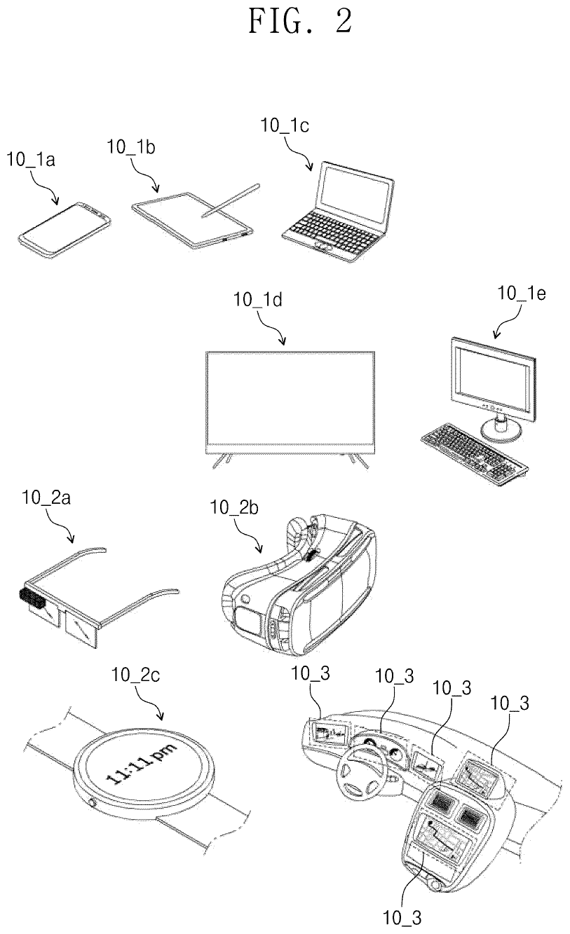

FIG. 2 illustrates schematic views of an electronic device according to various embodiments.

Referring to FIG. 2, the display device DD according to an embodiment of the present disclosure may be applied to various electronic devices. For example, various electronic devices, to which the display device DD according to an embodiment is applied, may include electronic devices for image display, such as a smartphone 10_1a, a tablet personal computer (PC) 10_1b, a laptop 10_1c, a television (TV) 10_1d, or a desk monitor 10_1e.

Furthermore, various electronic devices, to which the display device DD according to an embodiment is applied, may include wearable electronic devices, such as smart glasses 10_2a, a head mounted display 10_2b, or a smart watch 10_2c. Furthermore, various electronic devices, to which the display device DD according to an embodiment is applied, may include electronic devices 10_3 for vehicles, such as an instrument panel for a vehicle, a center fascia, a center information display (CID) disposed on a dashboard, or a room mirror display.

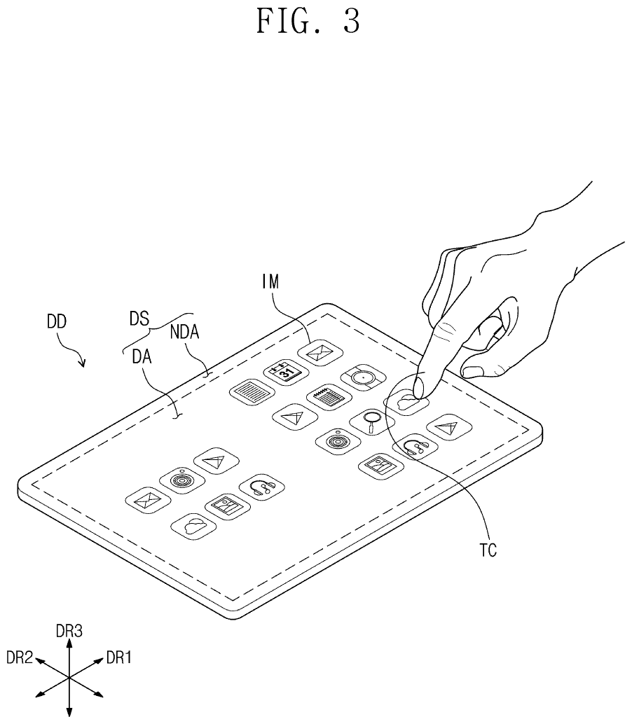

FIG. 3 is a perspective view of a display device according to an embodiment of the present disclosure.

Referring to FIG. 3, the display device DD according to an embodiment of the present disclosure may have long sides that extend in parallel in a first direction DR1 and short sides that extend in parallel in a second direction DR2 that crosses the first direction DR1. Corners of the display device DD, which connect the long sides and the short sides may have a curved shape. The corners of the display device DD having the curved shape may be defined as rounded corners. A shape of the display device DD may be defined as a round-cornered rectangular shape.

Hereinafter, a direction that is substantially perpendicular to a plane defined by the first direction DR1 and the second direction DR2 is defined as a third direction DR3. The third direction DR3 may be a thickness direction of the display device DD. Furthermore, in the specification, the meaning of “when viewed from above a plane” or “in a plan view” may be defined as “when viewed in the third direction DR3”.

A front surface of the display device DD may be defined as a display surface DS, and may have a plane defined by the first direction DR1 and the second direction DR2. Images IM generated by the display device DD may be provided to a user through the display surface DS.

The display surface DS may include a display area DA, and a non-display area NDA around the display area DA. The display area DA may display an image, and the non-display area NDA may not display an image. The non-display area NDA may surround the display area DA, and may define a periphery of the display device DD, which is printed in a specific color.

The display device DD may sense inputs that are applied from the outside of the display device DD. In an embodiment, for example, the display device DD may sense an input by a touch TC of the user.

Although not illustrated, the above-described electronic device ED may further include a camera and sensors that are disposed in the display device DD. The sensors may be proximity light sensors, but the types of sensors are not limited thereto. The camera may photograph an external image.

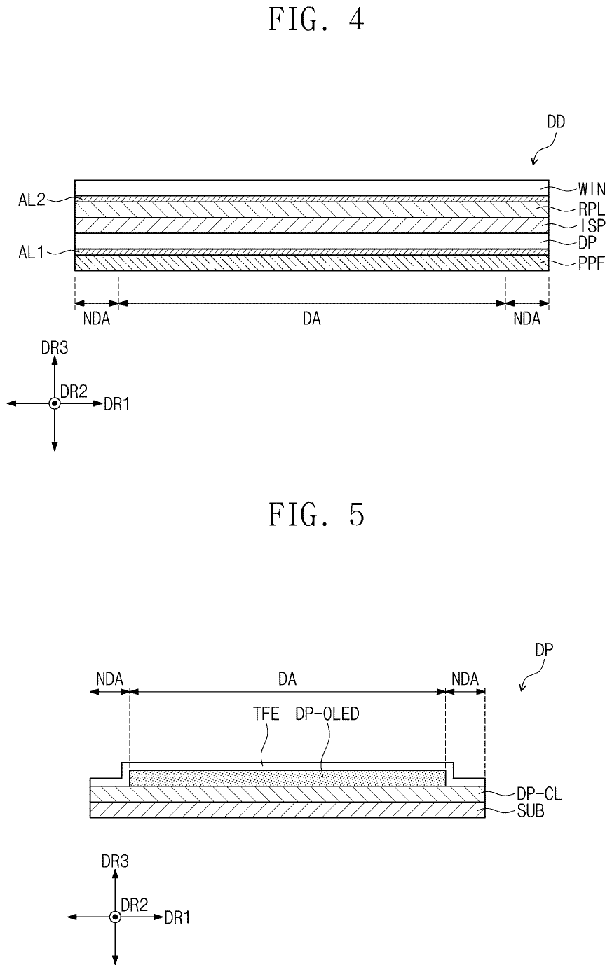

FIG. 4 is a view illustrating a cross section of the display device illustrated in FIG. 3, by way of example.

By way of example, FIG. 4 illustrates a cross section of the display device DD, when viewed in the second direction DR2.

Referring to FIG. 4, an embodiment of the display device DD may include a display panel DP, an input sensing part ISP, a reflection prevention layer RPL, a window WIN, a panel protection film PPF, and first and second adhesive layers AL1 and AL2. The above-described display module 11 may include the display panel DP, the input sensing part ISP, the reflection prevention layer RPL, and the panel protection film PPF illustrated in FIG. 4.

According to an embodiment of the present disclosure, the display panel DP may include a light emitting display panel. In an embodiment, for example, the display panel DP may be an organic light emitting display panel or an inorganic light emitting display panel. An emission layer of the organic light emitting display panel may include an organic light emitting material. An emission layer of the inorganic light emitting display panel may include quantum dots and quantum rods. Hereinafter, for convenience of description, embodiments where the display panel DP is an organic light emitting display panel will be mainly described.

The input sensing part ISP may be disposed on the display panel DP. The input sensing part ISP may include a plurality of sensing parts (not illustrated) for sensing an external input in a capacitive manner. When the display device DD is manufactured, the input sensing part ISP may be directly manufactured on the display panel DP. However, the present disclosure is not limited to this, and the input sensing part ISP may be integrated into the display panel DP to be manufactured together with the display panel DP, and this structure may be defined as an in-cell touch structure. In an embodiment, the input sensing part ISP may be manufactured as a separate panel from the display panel DP and be attached to the display panel DP by an adhesive layer.

The reflection prevention layer RPL may be disposed on the input sensing part ISP. When the display device DD is manufactured, the reflection prevention layer RPL may be directly manufactured on the input sensing part ISP. However, the present disclosure is not limited thereto, and the reflection prevention layer RPL may be manufactured as a separate panel, and may be attached to the input sensing part ISP by an adhesive layer.

The reflection prevention layer RPL may be defined as an external light reflection prevention film. The reflection prevention layer RPL may reduce a reflectance of external light that is input from a top surface of the display device DD toward the display panel DP. The external light may not be visually recognized by a user due to the reflection prevention layer RPL.

When external light directed toward the display panel DP is reflected from the display panel DP and is provided again to an external user, the user may visually recognize the external light, like a mirror. In an embodiment, the reflection prevention layer RPL may include a plurality of color filters for displaying the same colors as those of the pixels of the display panel DP to prevent the external light from being visually recognized.

In an embodiment, the color filters may filter the external light to the same colors as those of the pixels. In such an embodiment, the external light may not be visually recognized by the user. However, the present disclosure is not limited thereto, and the reflection prevention layer RPL may include a phase retarder and/or a polarizer to reduce the reflectance of the external light.

The window WIN may be disposed on the reflection prevention layer RPL. The window WIN may protect the display panel DP, the input sensing part ISP, and the reflection prevention layer RPL from external scratches and impacts.

The panel protection film PPF may be disposed under the display panel DP. The panel protection film PPF may protect a lower side of the display panel DP. The panel protection film PPF may include a flexible plastic material such as Polyethyleneterephthalate (PET).

The first adhesive layer AL1 may be interposed between the display panel DP and the panel protection film PPF, and the display panel DP and the panel protection film PPF may be bonded to each other by the first adhesive layer AL1. The second adhesive layer AL2 may be interposed between the window WIN and the reflection prevention layer RPL, and the window WIN and the reflection prevention layer RPL may be bonded to each other by the second adhesive layer AL2.

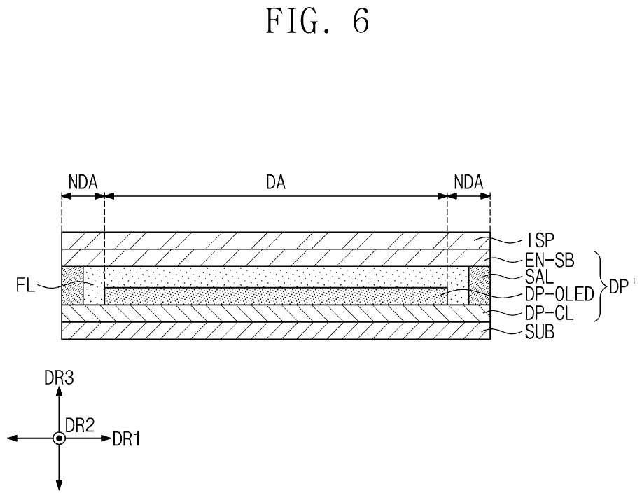

FIG. 5 is a view illustrating a cross section of a display panel illustrated in FIG. 4, by way of example.

By way of example, FIG. 5 illustrates a cross section of the display panel DP, when viewed in the second direction DR2.

Referring to FIG. 5, an embodiment of the display panel DP may include a substrate SUB, a circuit element layer DP-CL that is disposed on the substrate SUB, a display element layer DP-OLED that is disposed on the circuit element layer DP-CL, and a thin film encapsulation layer TFE that is disposed on the display element layer DP-OLED.

The substrate SUB may include a display area DA, and a non-display area NDA around the display area DA. The substrate SUB may include glass or may include a flexible plastic material, such as or polyimide (PI). The display element layer DP-OLED may be disposed on the display area DA.

A plurality of pixels may be disposed on the circuit element layer DP-CL and the display element layer DP-OLED. Each of the pixels may include a transistor that is disposed on the circuit element layer DP-CL and a light emitting element that is disposed on the display element layer DP-OLED and is connected to the transistor.

A thin film encapsulation layer TFE may be disposed on the circuit element layer DP-CL to cover the display element layer DP-OLED. The thin film encapsulation layer TFE may protect pixels from moisture, oxygen, and foreign objects. In an embodiment, the above-described input sensing part ISP may be disposed directly on the thin film encapsulation layer TFE.

FIG. 6 is a view illustrating a cross section of a display panel according to another embodiment of the present disclosure.

By way of example, FIG. 6 illustrates a cross section of a display panel DP′ when viewed in the second direction DR2, and illustrates the input sensing part ISP together with the display panel DP′.

Referring to FIG. 6, an embodiment of the display panel DP′ may include a substrate SUB, a circuit element layer DP-CL, a display element layer DP-OLED, an encapsulation substrate EN-SB, a sealing layer SAL, and a filler FL. T he circuit element layer DP-CL may be disposed on the substrate SUB, and the display element layer DP-OLED may be disposed on the circuit element layer DP-CL. The encapsulation substrate EN-SB may be disposed on the display element layer DP-OLED. The input sensing part ISP may be disposed directly on the encapsulation substrate EN-SB. The substrate SUB and the encapsulation substrate EN-SB may be of rigid type.

The sealing layer SAL may be interposed between the substrate SUB and the encapsulation substrate EN-SB. The sealing layer SAL may be disposed on the non-display area NDA. The sealing layer SAL may bond the substrate SUB and the encapsulation substrate EN-SB. The display element layer DP-OLED may be sealed between the substrate SUB and the encapsulation substrate EN-SB by the sealing layer SAL. The sealing layer SAL may include a photocurable material.

The filler FL may be disposed between the substrate SUB and the encapsulation substrate EN-SB. The filler FL may be disposed in a space sealed by the sealing layer SAL between the substrate SUB and the encapsulation substrate EN-SB. The filler FL may include a thermosetting material.

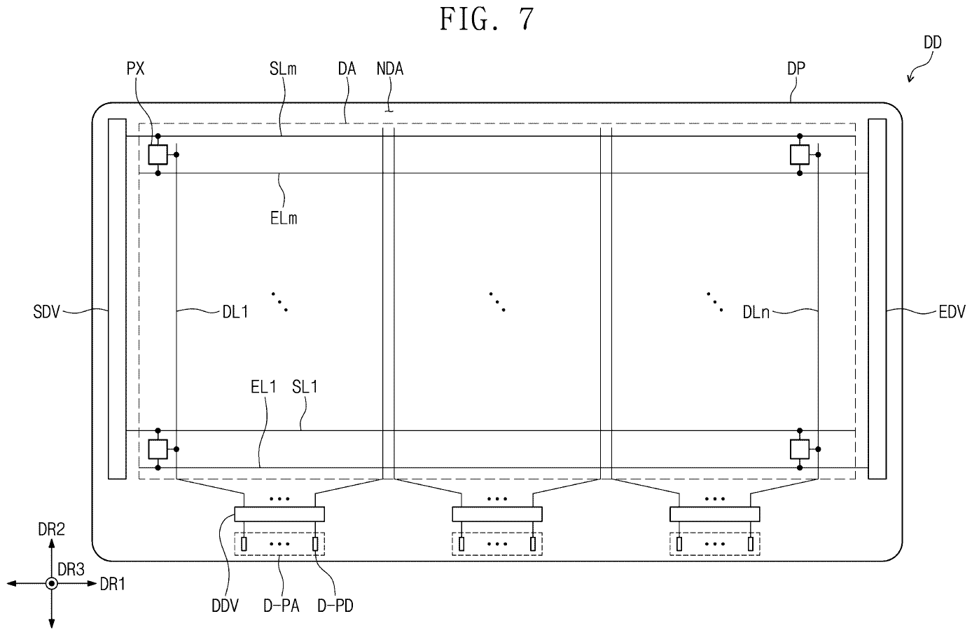

FIG. 7 is a plan view of a display device illustrated in FIG. 4.

Referring to FIG. 7, an embodiment of the display device DD may include the display panel DP, a scan driver SDV, a plurality of data drivers DDV, an emission driver EDV, and a plurality of pads PD.

The display panel DP may have long sides that extend in the first direction DR1 and short sides that extend in the second direction DR2. Corner portions of the display panel DP, which connect the long sides and the short sides, may have an outwardly convex curved shape.

The display panel DP may include a plurality of pixels PX, a plurality of scan lines SL1 to SLm, a plurality of data lines DL1 to DLn, and a plurality of emission lines EL1 to ELm. Here, each of “m” and “n” is a natural number. Areas of the display panel DP on a plane may include a display area DA, and a non-display area NDA that surrounds the display area DA.

The pixels PX may be disposed in the display area DA. The scan driver SDV and the emission driver EDV may be disposed in the non-display area NDA that is adjacent to opposite sides of the display panel DP, which are opposite to each other in the first direction. The data drivers DDV may be disposed in a non-display area NDA that is adjacent to one of opposite sides of the display panel DP, which are opposite to each other in the second direction DR2. When viewed on a plane or in a plan view, the data drivers DDV may be adjacent to a lower end of the display panel DP.

The scan lines SL1 to SLm may extend in the first direction DR1 to be connected to the pixels PX and the scan driver SDV. The data lines DL1 to DLn may extend in the first direction DR1 to be connected to the pixels PX and the data driver DDV. The emission lines EL1 to ELm may extend in the first direction DR1 to be connected to pixels PX and the emission driver EDV.

The data drivers DDV may be arranged in the first direction DR1. A specific or predetermined number of data lines may be connected to each of the data drivers DDV. By way of example, three data drivers DDV are illustrated in FIG. 7, but the number of the data drivers DDV is not limited thereto. In an embodiment, for example, as the left and right areas of the display panel DP increase, the number of data drivers DDV may also increase.

The pads D-PD may be disposed in the non-display area NDA that is adjacent to a lower end of the display panel DP. The pads D-PD may be closer to a lower end of the display panel DP than to the data drivers DDV. The data drivers DDV may be connected to the pads D-PD. The data lines DL1 to DLn may be connected to the data drivers DDV, and the data drivers DDV may be connected to pads D-PD corresponding to the data lines DL1 to DLn.

A plurality of pad areas D-PA corresponding to the data drivers DDV, respectively, may be defined on the display panel DP. The pad areas D-PA may be closer to a lower end of the display panel DP than to the data drivers DDV. The pad areas D-PA may be arranged in the first direction DR1, and may be adjacent to the data drivers DDV in the second direction DR2, respectively. A specific or predetermined number of pads D-PD may be disposed on each of the pad areas D-PA.

Although not illustrated in drawings, the display device DD may further include a timing controller for controlling operations of the scan driver SDV, the data drivers DDV, and the emission driver EDV. The timing controller may be connected to the pads D-PD through a printed circuit board. However, the present disclosure is not limited thereto, and the timing controller may be manufactured as (or defined by) an integrated circuit (IC) with the data drivers DDV and be mounted on the display panel DP. Furthermore, the timing controller and the data drivers DDV may be manufactured as an IC and be connected to the display panel DP through a flexible circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The emission driver EDV may generate a plurality of emission signals, and the emission signals may be applied to the pixels PX through the emission lines EL1 to ELm.

The pixels PX may receive the data voltages in response to the scan signals. The pixels PX may display an image by emitting light of a luminance corresponding to the data voltages in response to the emission signals.

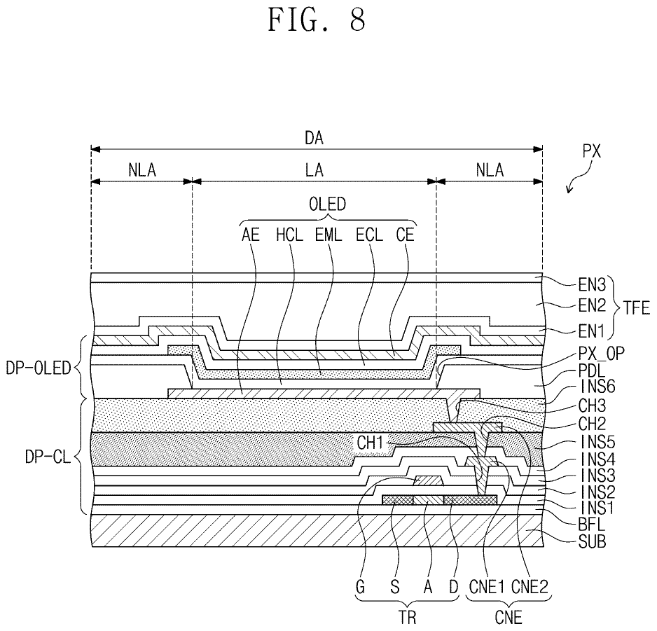

FIG. 8 is a diagram illustrating a cross section of one pixel illustrated in FIG. 7.

Referring to FIG. 8, in an embodiment, a pixel PX may include a transistor TR and a light emitting element OLED. The light emitting element OLED may include a first electrode AE (or an anode), a second electrode CE (or a cathode), a hole control layer HCL, an electron control layer ECL, and an emission layer EML.

The transistor TR and the light emitting element OLED may be disposed on the substrate SUB. Although one transistor TR is illustrated in FIG. 8 for convenience of illustration, the pixel PX may include a plurality of transistors and at least one capacitor for driving the light emitting element OLED.

The display area DA may include an emission area LA corresponding to each of the pixels PX and a non-emission area NLA around the emission area LA. The light emitting element OLED may be disposed in the emission area LA.

A buffer layer BFL may be disposed on the substrate SUB, and the buffer layer BFL may be an inorganic layer. A semiconductor pattern may be disposed on the buffer layer BFL. The semiconductor pattern may include polysilicon, amorphous silicon, or metal oxide.

The semiconductor pattern may be doped with an N-type dopant or a P-type dopant. The semiconductor pattern may include a highly-doped area and a lightly-doped area. A conductivity of the highly-doped area may be greater than that of the lightly-doped area, and may serve as a source electrode and a drain electrode of the transistor TR. The lightly-doped area may substantially correspond to an active (or a channel) of the transistor.

A source “S”, an active “A”, and a drain “D” of the transistor TR may be formed from the semiconductor pattern. A first insulating layer INS1 may be disposed on the semiconductor pattern. A gate “G” of the transistor TR may be disposed on the first insulating layer INS1. A second insulating layer INS2 may be disposed on the gate “G”. A third insulating layer INS3 may be disposed on the second insulating layer INS2.

To connect the transistor TR and the light emitting element OLED, a connection electrode CNE may include a first connection electrode CNE1 and a second connection electrode CNE2. The first connection electrode CNE1 may be disposed on the third insulating layer INS3 and may be connected to the drain “D” through a first contact hole CH1 defined in the first to third insulating layers INS1 to INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 through a second contact hole CH2 that is defined in the fourth and fifth insulating layers INS4 and INS5.

The second connection electrode CNE2 may be disposed on a sixth insulating layer INS6. Layers from the buffer layer BFL to the sixth insulating layer INS6 may be defined as a circuit element layer DP-CL. The first to sixth insulating layers INS1 to INS6 may be inorganic layers or organic layers.

The first electrode AE may be disposed on the sixth insulating layer INS6. The first electrode AE may be connected to the second connection electrode CNE2 through a third contact hole CH3 that is defined in the sixth insulating layer INS6. A pixel definition film PDL, in which an opening PX_OP for exposing a specific portion of the first electrode AE is defined, may be disposed on the first electrode AE and the sixth insulating layer INS6.

The hole control layer HCL may be disposed on the first electrode AE and the pixel definition film PDL. The hole control layer HCL may include a hole transport layer and a hole injection layer.

The emission layer EML may be disposed on the hole control layer HCL. The emission layer EML may be disposed in an area corresponding to the opening PX_OP. The emission layer EML may include an organic material and/or an inorganic material. The emission layer EML may generate one of red light, green light, and blue light.

The electron control layer ECL may be disposed on the emission layer EML and the hole control layer HCL. The electron control layer ECL may include an electron transport layer and an electron injection layer. The hole control layer HCL and the electron control layer ECL may be disposed in common in an emission area LA and a non-emission area NLA.

The second electrode CE may be disposed on the electron control layer ECL. The second electrode CE may be disposed in the pixels PX in common. The layer, in which the light emitting element OLED is disposed, may be defined as a display element layer DP-OLED.

The thin film encapsulation layer TFE may be disposed on the second electrode CE to cover the pixel PX. The thin film encapsulation layer TFE may include a first encapsulation layer EN1 that is disposed on the second electrode CE, a second encapsulation layer EN2 that is disposed on the first encapsulation layer EN1, and a third encapsulation layer EN3 that is disposed on the second encapsulation layer EN2.

Each of the first and third encapsulation layers EN1 and EN3 may include an inorganic insulating layer, and may protect the pixel PX from moisture/oxygen. The second encapsulation layer EN2 includes an organic insulating layer and may protect the pixel PX from foreign objects such as dust particles.

A first voltage may be applied to the first electrode AE through the transistor TR, and a second voltage having a lower level than that of the first voltage may be applied to the second electrode CE. Excitons may be formed by coupling holes and electrons that are injected into the emission layer EML, and as the excitons transit to a ground state, the light emitting element OLED may emit light.

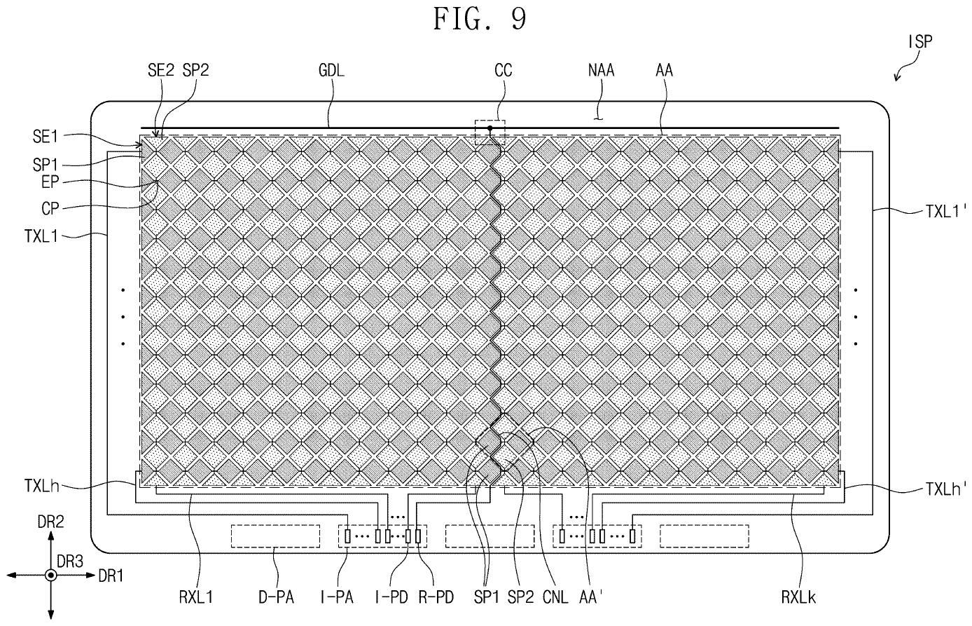

FIG. 9 is a plan view of an input sensing part illustrated in FIG. 4.

By way of example, in FIG. 9, the pad areas D-PA described above are illustrated together with the input sensing part ISP. In FIG. 9, the pad areas D-PA are illustrated by dotted lines.

Referring to FIG. 9, in an embodiment, the input sensing part ISP may include a plurality of sensing electrodes SE1 and SE2, a plurality of sensing lines TXL1 to TXLh, TXL1′ to TXLh′, and RXL1 to RXLk, a guard line GDL, a connection line CNL, a plurality of first pads I-PD, and a second pad R-PD. Here, each of ‘h’ and ‘k’may be a natural number.

In an embodiment, the sensing electrodes SE1 and SE2, the sensing lines TXL1 to TXLh, TXL1′ to TXLh′, and RXL1 to RXLk, the guard line GDL, the connection line CNL, the first pads I-PD, and the second pad R-PD may be disposed on the above-described thin film encapsulation layer TFE or on the above-described encapsulation substrate EN-SB.

When viewed on a plane or in a plan view, a planar area of the input sensing part ISP may include an active area AA and a non-active area NAA around the active area AA. The non-active area NAA may surround the active area AA. When viewed on a plane or in a plan view, the active area AA may overlap the display area DA and the non-active area NAA may overlap the non-display area NDA.

The sensing electrodes SE1 and SE2 may be disposed in the active area AA. The sensing electrodes SE1 and SE2 may include a plurality of first sensing electrodes SE1 that are disposed in the active area AA and a plurality of second sensing electrodes SE2 that are disposed in the active area AA.

The first sensing electrodes SE1 may extend in the first direction DR1 to be arranged in the second direction DR2. The second sensing electrodes SE2 may extend in the second direction DR2 to be arranged in the first direction DR1. The second sensing electrodes SE2 may extend to cross the first sensing electrodes SE1 while being insulated from the first sensing electrodes SE1.

The sensing lines TXL1 to TXLh, TXL1′ to TXLh′, and RXL1 to RXLk may be connected to the sensing electrodes SE1 and SE2, and may extend to a non-active area NAA. The sensing lines TXL1 to TXLh, TXL1′ to TXLh′, and RXL1 to RXLk may extend to a non-active area NAA that is adjacent to a lower side of the active area AA.

The sensing lines TXL1 to TXLh, TXL1′ to TXLh′, and RXL1 to RXLk may include a plurality of first sensing lines TXL1 to TXLh and TXL1′ to TXLh′ that are connected to the first sensing electrodes SE1 and a plurality of second sensing lines RXL1 to RXLk that are connected to the second sensing electrodes SE2. The first sensing lines TXL1 to TXLh and TXL1′ to TXLh′ may be defined as transmission lines that transmit a driving signal. The second sensing lines RXL1 to RXLk may be defined as reception lines that receive sensing signals sensed by the first and second sensing electrodes SE1 and SE2.

The first sensing lines TXL1 to TXLh may be connected to ones of opposite ends of the first sensing electrodes SE1, which are opposite to each other in the first direction DR1. The first sensing lines TXL1′ to TXLh′ may be connected to the other ones of the opposite ends of the first sensing electrodes SE1, which are opposite to each other in the first direction DR1.

The first sensing lines TXL1 to TXLh may extend to a non-active area (e.g., a left non-active area) that is adjacent to the ones of the ends of the first sensing electrodes SE1 and a non-active area NAA (e.g., a lower non-active area) that is adjacent to a lower side of the active area AA. The first sensing lines TXL1′ to TXLh′ may extend to a non-active area (e.g., a right non-active area) that is adjacent to the other ones of the ends of the first sensing electrodes SE1 and the non-active area NAA (e.g., the lower non-active area) that is adjacent to the lower side of the active area AA.

The second sensing lines RXL1 to RXLk may be connected to ones of opposite ends of the second sensing electrodes SE2, which are opposite to each other in the second direction DR2. The ones of the ends of the second sensing electrodes SE2 may be adjacent to the lower side of the active area AA. The second sensing lines RXL1 to RXLk may extend to the non-active area NAA (e.g., the lower non-active area) that is adjacent to the lower side of the active area AA.

The first pads I-PD and the second pad R-PD may be disposed in the non-active area NAA. The first pads I-PD and the second pad R-PD may be disposed in the non-active area NAA (e.g., the lower non-active area) that is adjacent to the lower side of the active area AA when viewed on a plane or in a plan view.

A plurality of pad areas I-PA may be defined in the input sensing part ISP. The pad areas I-PA may be spaced apart from each other in the first direction DR1. The pad areas I-PA may be disposed between the pad areas D-PA of the display panel DP. Accordingly, when viewed on a plane or in a plan view, the pad areas I-PA may not overlap the pad areas D-PA. Although not illustrated, an input sensing controller that controls an operation of the input sensing part ISP may be connected to the pads I-PD through a printed circuit board.

A specific or predetermined number of first pads I-PD may be disposed on each of the pad areas I-PA. The second pad R-PD may be disposed in any one of the pad areas I-PA.

The sensing lines TXL1 to TXLh, TXL1′ to TXLh′, and RXL1 to RXLk may be connected to the first pads I-PD in the non-active area NAA. The first sensing lines TXL1 to TXLh may be connected to the first pads I-PD disposed in a corresponding one of the pad areas I-PA. The first sensing lines TXL1′ to TXLh′ may be connected to the first pads I-PD disposed in another corresponding one of the pad areas I-PA.

In an embodiment, for example, the first sensing lines TXL1 to TXLh may be connected to ones of the first pads I-PD, which are disposed on the left side. In an embodiment, for example, the first sensing lines TXL1′ to TXLh′ may be connected to ones of the pad areas I-PA, which are disposed on the right side.

A specific or predetermined number of second sensing lines, among the second sensing lines RXL1 to RXLk, may be connected to the first pads I-PD disposed on the pad areas I-PA, respectively. In an embodiment, for example, the second sensing lines disposed on the left side of a central portion of the input sensing part ISP in the first direction DR1 may be connected to the first pads I-PD disposed in the pad area I-PA disposed on the left side. In an embodiment, for example, the second sensing lines disposed on the right side of the central portion of the input sensing part ISP in the first direction DR1 may be connected to the first pads I-PD disposed in the pad area I-PA disposed on the right side.

A driving signal may be applied to the first sensing electrodes SE1 through the first sensing lines TXL1 to TXLh and TXL1′ to TXLh′. A change in a capacitance formed between the first and second sensing electrodes SE1 and SE2 may be output through the second sensing lines RXL1 to RXLk as a sensing signal.

Each of the first sensing electrodes SE1 may include a plurality of first sensing parts SP1 that are arranged in the first direction DR1 and a plurality of connection patterns CP that connect the first sensing parts SP1. In an embodiment, for example, the first sensing parts SP1 may have a rhombus shape in a plan view. Each of the connection patterns CP may be disposed between the two first sensing parts SP1 to connect the two first sensing parts SP1.

Each of the second sensing electrodes SE2 may include a plurality of second sensing parts SP2 that are arranged in the second direction DR2 and a plurality of extension patterns EP that extend from the second sensing parts SP2. In an embodiment, for example, the second sensing parts SP2 may have a rhombus shape. In each of the second sensing electrodes SE2, the extension patterns EP may be integrally formed with the second sensing parts SP2. Each of the extension patterns EP may be disposed between the two second sensing parts SP2 and extend from the two second sensing parts SP2.

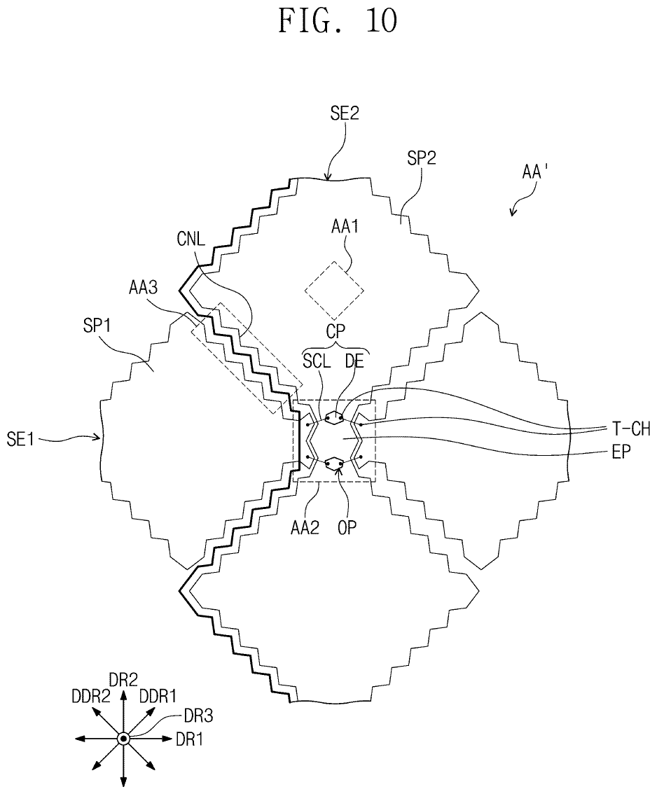

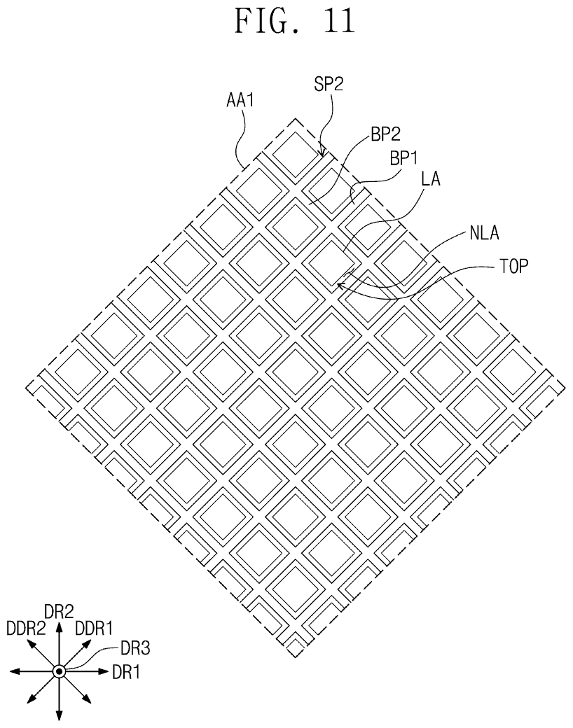

A more detailed shape of the first and second sensing parts SP1 and SP2 and a more detailed configuration of the connection patterns CP and the extension patterns EP will be described in detail with reference to FIGS. 10 and 11.

When viewed on a plane or in a plan view, the extension patterns EP may extend to cross the connection patterns CP. The first sensing parts SP1 and the second sensing parts SP2 may be spaced apart from each other without overlapping each other, and may be alternately disposed. A capacitance may be formed by the first sensing parts SP1 and the second sensing parts SP2. The first and second sensing parts SP1 and SP2 and the extension patterns EP may be disposed on the same layer.

The guard line GDL may be disposed in a non-active area NAA. In an embodiment, for example, when viewed on a plane or in a plan view, the guard line GDL may be disposed in a non-active area NAA (e.g., an upper non-active area) that is adjacent to an upper side of the active area AA. The guard line GDL may extend in the first direction DR1.

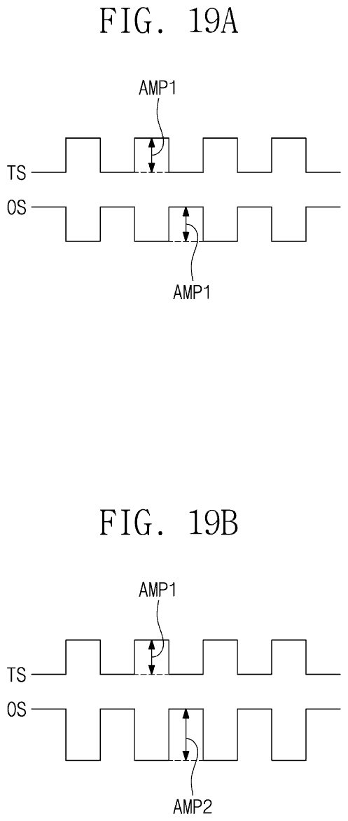

The connection line CNL may be disposed in the non-active area NAA (e.g., the lower non-active area) that is adjacent to the lower side of the active area AA, when viewed on a plane or in a plan view. The connection line CNL may be connected to the second pad R-PD. An offset signal having a phase that is opposite to that of the driving signal applied to the first sensing lines TXL1 to TXLh and TXL1′ to TXLh′ may be applied to the connection line CNL through the second pad R-PD. The offset signal will be illustrated in FIGS. 19A and 19B below.

The connection line CNL may extend toward the guard line GDL via the active area AA, when viewed on a plane or in a plan view. The connection line CNL may extend to the non-active area NAA (e.g., the upper non-active area) that is adjacent to the upper side of the active area AA to be connected to the guard line GDL. Accordingly, the offset signal may be applied to the guard line GDL through the connection line CNL.

In an embodiment, for example, the connection line CNL may extend along a central portion of the active area AA. The connection line CNL may extend via an area between any one second sensing electrode SE2 and the first sensing electrodes SE1 that is adjacent to the any one second sensing electrode SE2 in the active area AA. Any one second sensing electrode SE2 that is adjacent to an extension path of the connection line CNL may be disposed at a central portion of the active area AA. Hereinafter, one second sensing electrode SE2 that is adjacent to the extension path of the connection line CNL is defined as a selected second sensing electrode SE2.

The connection line may extend via an area between the second sensing parts SP2 of the selected second sensing electrode SE2 and the first sensing parts SP1 that are adjacent to the second sensing parts SP2 of the selected second sensing electrode SE2. The connection line CNL may have a shape that is continuously bent to pass between the first and second sensing parts SP1 and SP2 having a rhombus shape. Accordingly, the connection line CNL may have a zigzag shape in the active area AA and extend in the second direction DR2.

FIG. 10 is an enlarged view of area AA′ illustrated in FIG. 9.

By way of example, two first sensing parts SP1 and two second sensing parts SP2 that are adjacent to the connection line CNL are illustrated in FIG. 10.

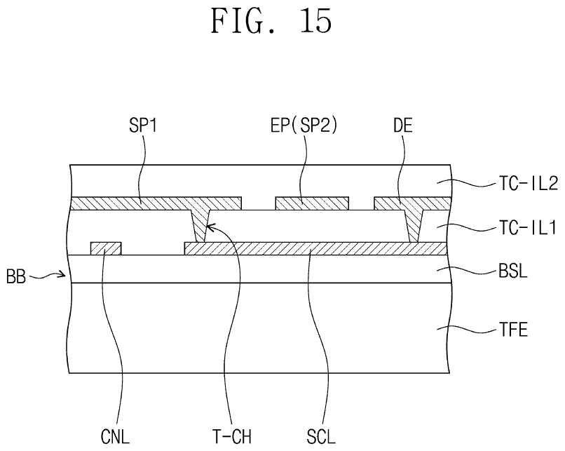

Referring to FIG. 10, in an embodiment, the first sensing electrode SE1 may include a connection pattern CP that is disposed between two first sensing parts SP1 and the first sensing parts SP1 that are arranged in the first direction DR1 to connect the first sensing parts SP1 to each other. The connection pattern CP may be connected to the first sensing parts SP1 through the contact holes T-CH. A cross-sectional configuration of the contact holes T-CH is illustrated in FIG. 15.

The second sensing electrode SE2 may include an extension pattern EP that is disposed between the two second sensing parts SP2 and the second sensing parts SP2 that are arranged in the second direction DR2 to extend from the second sensing parts SP2. The extension pattern EP may overlap the connection pattern CP when viewed on a plane or in a plan view. The extension pattern EP may extend to cross the connection pattern CP while being insulated from the connection pattern CP. The extension pattern EP may be integrally formed with the second sensing parts SP2 as a single unitary indivisible part.

The first sensing parts SP1 and the second sensing parts SP2 may be disposed alternately with each other. In an embodiment, for example, the first sensing parts SP1 and the second sensing parts SP2 may be disposed in a first diagonal direction DDR1 and a second diagonal direction DDR2.

The first diagonal direction DDR1 may be defined as a direction that crosses the first and second directions DR1 and DR2 on a plane defined by the first and second directions DR1 and DR2. The second diagonal direction DDR2 may be defined as a direction that crosses the first diagonal direction DDR1 on a plane defined by the first and second directions DR1 and DR2. In an embodiment, for example, the first direction DR1 and the second direction DR2 may perpendicularly cross each other, and the first diagonal direction DDR1 and the second diagonal direction DDR2 may perpendicularly cross each other.

The connection pattern CP may be disposed between the second sensing parts SP2. The extension pattern EP may be disposed between the first sensing parts SP1.

The connection pattern CP may include a plurality of sensor connection lines SCL and a plurality of dummy electrodes DE. The sensor connection lines SCL may be disposed between the first sensing parts SP1 in the first direction DR1 to be connected to the first sensing parts SP1. The sensor connection lines SCL may be connected to the first sensing parts SP1 through the contact holes T-CH. The extension pattern EP may overlap the sensor connection lines SCL, when viewed on a plane or in a plan view.

The dummy electrodes DE may be disposed between the sensor connection lines SCL in the first direction DR1 to be connected to the sensor connection lines SCL. The dummy electrodes DE may be connected to the sensor connection lines SCL through the contact holes T-CH. Openings OP may be defined in the extension pattern EP. The dummy electrodes DE may be disposed in the openings OP, respectively.

Peripheries (or side ends) of the first sensing parts SP1 and peripheries of the second sensing parts SP2 may be continuously bent to have a zigzag shape or sawtooth-like shape, but the shapes of the peripheries of the first and second sensing parts SP1 and SP2 are not limited thereto.

The connection line CNL may extend via an area between one (e.g., a left first sensing part SP1) of the first sensing parts SP1 and the second sensing parts SP2. The connection line CNL may extend in a zigzag shape to extend while passing through areas between the peripheries of the first and second sensing parts SP1 and SP2 having a zigzag shape.

The connection line CNL may overlap a portion of one first sensing part SP1 to cross a portion of one first sensing part SP1, when viewed on a plane or in a plan view. The connection line CNL may extend to detour around the sensor connection lines SCL not to overlap the sensor connection lines SCL, when viewed on a plane or in a plan view.

The connection line CNL may be adjacent to the contact holes T-CH that overlap one first sensing part SP1. The connection line CNL may extend to detour around the contact holes T-CH not to overlap the contact holes T-CH that overlap one first sensing part SP1, when viewed on a plane or in a plan view.

FIG. 11 is an enlarged view of a first area AA1 illustrated in FIG. 10.

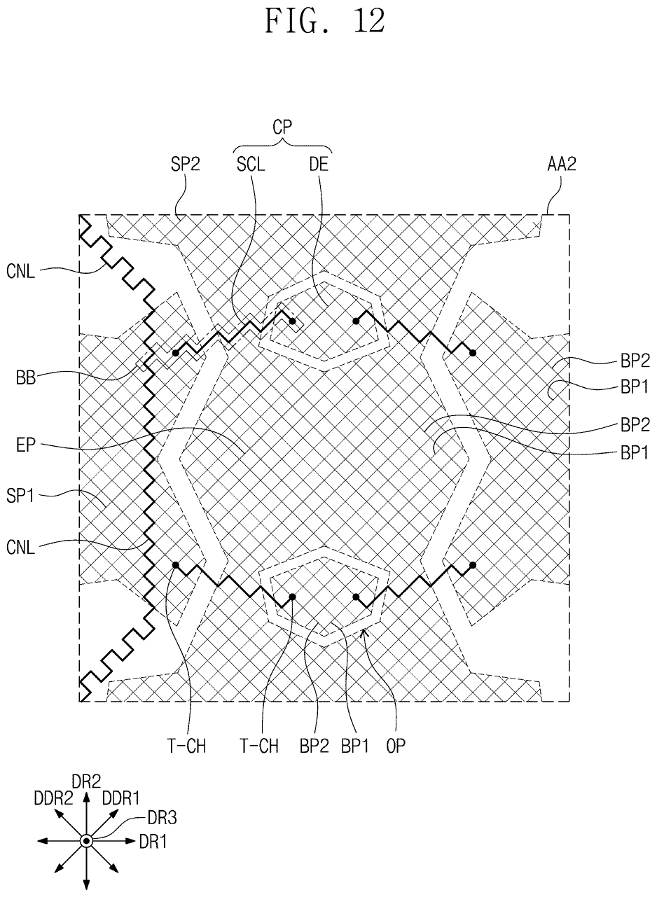

Referring to FIG. 11, in an embodiment, a second sensing part SP2 may have a mesh shape. In such an embodiment, a first sensing part SP1 may also have a mesh shape that is similar to that of the second sensing part SP2 as illustrated in FIG. 12.

The second sensing part SP2 may include a plurality of first branch parts BP1 that extend in the first diagonal direction DDR1 and a plurality of second branch parts BP2 that extend in the second diagonal direction DDR2.

The first branch parts BP1 and the second branch parts BP2 may cross each other and may be integrally formed with each other as a single unitary indivisible part. Rhombus-shaped openings TOP may be defined by the first branch parts BP1 and the second branch parts BP2 that cross each other. The first and second branch parts BP1 and BP2 may be defined as mesh lines, and the line width of each of the mesh lines may be several micrometers. The first and second branch parts BP1 and BP2 may include metal.

The emission areas LA may have a rhombus shape and may be disposed to overlap the openings TOP. The emission area LA illustrated in FIG. 8 may be any one of the emission areas LA illustrated in FIG. 11. The first and second branch parts BP1 and BP2 may be disposed to overlap the non-emission area NLA.

Because the first and second branch parts BP1 and BP2 are disposed in the non-emission area NLA, the light generated in the emission areas LA may be normally emitted without being affected by the first and second branch parts BP1 and BP2.

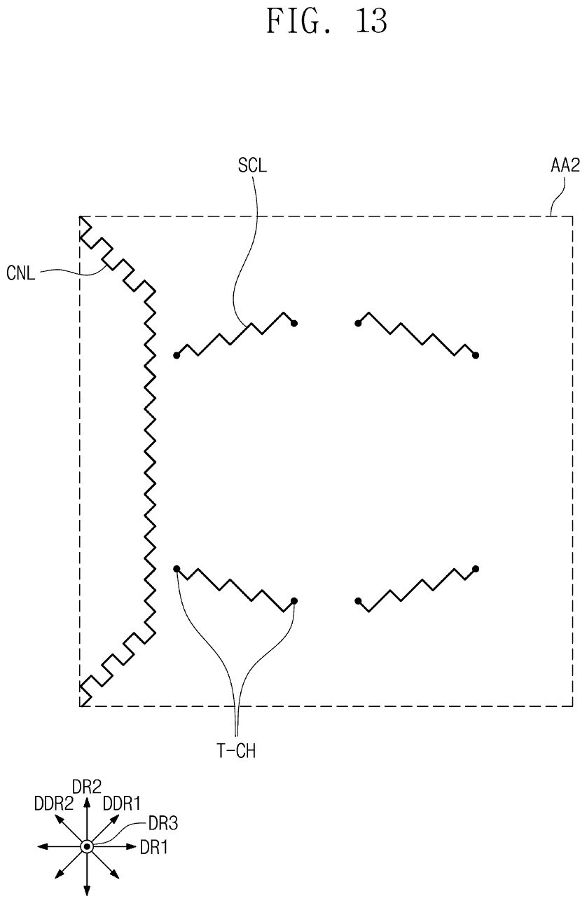

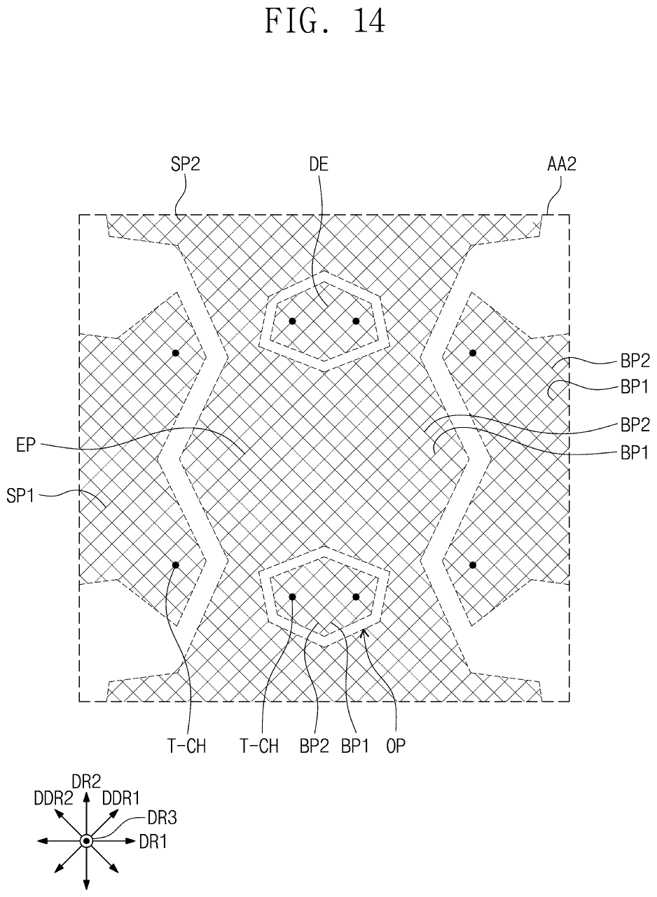

FIG. 12 is an enlarged view of a second area AA2 illustrated in FIG. 10. FIG. 13 is a view separately illustrating a connection line and sensor connection lines that are disposed on the same layer in FIG. 12. FIG. 14 is a view separately illustrating first sensing parts, dummy electrodes, and an extension pattern that are disposed on the same layer in FIG. 12.

By way of example, in FIGS. 12 to 14, the first and second branch parts BP1 and BP2 are illustrated as being relatively smaller than the first and second branch parts BP1 and BP2 illustrated in FIG. 11, and are illustrated in a line shape. Furthermore, in FIGS. 12 to 14, the emission areas LA and the non-emission areas NLA are omitted for convenience of illustration.

Referring to FIGS. 12, 13, and 14, in an embodiment, the first sensing parts SP1, the dummy electrodes DE, and the extension pattern EP may have a mesh shape like the second sensing part SP2. In an embodiment, for example, each of the first sensing parts SP1, the dummy electrodes DE, and the extension pattern EP may include a plurality of first branch parts BP1 that extend in the first diagonal direction DDR1 and a plurality of second branch parts BP2 that extend in the second diagonal direction DDR2, like the second sensing part SP2.

In each of the first sensing parts SP1, the dummy electrodes DE, and the extension pattern EP, the first branch parts BP1 and the second branch parts BP2 may cross each other and may be integrally formed with each other as a single unitary indivisible part. The first and second branch parts BP1 and BP2 of each of the first sensing parts SP1, the dummy electrodes DE, and the extension pattern EP may overlap the non-emission area NLA.

The sensor connection lines SCL may be continuously bent in the first diagonal direction DDR1 and the second diagonal direction DDR2 to extend from the first sensing parts SP1 to the dummy electrodes DE. The sensor connection lines SCL may overlap the first and second branch parts BP1 and BP2 of a portion of the first sensing parts SP1 and the first and second branch parts BP1 and BP2 of a portion of the dummy electrodes DE. Each of the sensor connection lines SCL may be defined as a single line.

The connection line SCL may be continuously bent in the first diagonal direction DDR1 and the second diagonal direction DDR2, and may extend in a zigzag shape. The connection line SCL has a zigzag shape, and may extend via an area between one first sensing part SP1 and the second sensing parts SP2. The connection line SCL having a zigzag shape may extend to cross a portion of one first sensing part SP1. That is, the connection line SCL that extends in a zigzag shape may overlap a portion of one first sensing part SP1.

The connection line SCL may overlap the first and second branch parts BP1 and BP2 of a portion of one first sensing part SP1. The connection line SCL may extend to detour around the sensor connection lines SCL and the contact holes T-CH without overlapping the sensor connection lines SCL and the contact holes T-CH in one first sensing part SP1.

Referring to FIGS. 10, 12, and 13, the connection line CNL and the sensor connection lines SCL may be disposed in (or directly on) a same layer as each other. The connection line CNL and the sensor connection lines SCL may be defined as portions of a same conductive pattern CP, e.g., a first conductive pattern.

Referring to FIGS. 10, 11, 12, and 14, the first sensing parts SP1, the second sensing parts SP2, the dummy electrodes DE, and the extension pattern EP may be disposed in (or directly on) a same layer as each other. The first and second sensing parts SP1 and SP2, the dummy electrodes DE, and the extension pattern EP may be defined as portions of a same conductive pattern, e.g., a second conductive pattern.

The first sensing parts SP1, the second sensing parts SP2, the dummy electrodes DE, and the extension pattern EP may be disposed in a layer that is different from a layer in which the connection line CNL and the sensor connection lines SCL are disposed. In an embodiment, for example, the first sensing parts SP1, the second sensing parts SP2, the dummy electrodes DE, and the extension pattern EP may be disposed on the connection line SCL and the sensor connection lines SCL.

FIG. 15 is a cross-sectional view of area BB illustrated in FIG. 12.

Referring to FIG. 15, in an embodiment, a base layer BSL may be disposed on the thin film encapsulation layer TFE. The base layer BSL may include an inorganic insulating layer. The connection line CNL and the sensor connection line SCL may be disposed on the base layer BSL and may be disposed in (or directly on) a same layer as each other.

A first touch insulating layer TC-IL1 may be disposed on the connection line CNL and the sensor connection line SCL. The first touch insulating layer TC-IL1 may be disposed on the base layer BSL to cover the connection line CNL and the sensor connection line SCL. The first touch insulating layer TC-IL1 may include an inorganic insulating layer or an organic insulating layer.

The first sensing part SP1, a connection pattern EP, the second sensing part SP2 integrally formed with the connection pattern EP, and a dummy electrode DE may be disposed on the first touch insulating layer TC-IL1 to be disposed on the same layer. Accordingly, the connection line CNL and the sensor connection line SCL may be disposed under the first sensing part SP1, the connection pattern EP, the second sensing part SP2, and the dummy electrode DE.

The first sensing part SP1 may be connected to the sensor connection line SCL through the contact holes T-CH defined in the first touch insulating layer TC-IL1 disposed between the first sensing part SP1 and the sensor connection line SCL. A second touch insulating layer TC-IL2 may be disposed on the first sensing part SP1, the connection pattern EP, the second sensing part SP2, and the dummy electrode DE. The second touch insulating layer TC-IL2 may be disposed on the first touch insulating layer TC-IL1 to cover the first sensing part SP1, the connection pattern EP, the second sensing part SP2, and the dummy electrode DE.

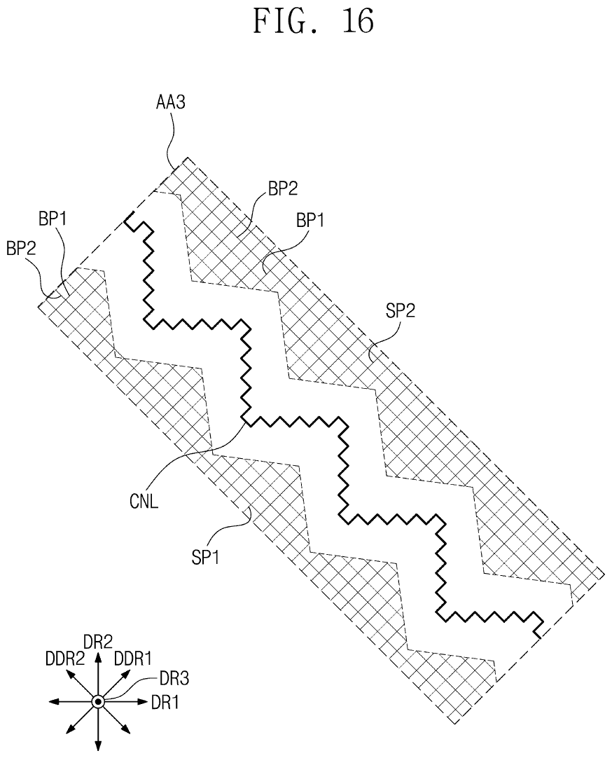

FIG. 16 is an enlarged view of third area AA3 illustrated in FIG. 10.

Referring to FIGS. 12 and 16, in an embodiment, a connection line CNL may be defined as a single line. The connection line CNL may extend to pass between the first sensing part SP1 and the second sensing part SP2. The connection line CNL may extend along the peripheries of the first and second sensing parts SP1 and SP2 having a zigzag shape. The connection line CNL may be repeatedly bent in the first and second diagonal directions DDR1 and DDR2 to correspond to extension directions of the first and second branch parts BP1 and BP2 to extend.

FIG. 17 is an enlarged view of area CC illustrated in FIG. 9.

Referring to FIG. 17, in an embodiment, a connection line CNL that extends from the active area AA to pass between the first sensing part SP1 and the second sensing part SP2 may extend from the non-active area NAA in the second direction DR2. The connection line CNL may be connected to the guard line GDL through a contact hole T-CH′ in the non-active area NAA.

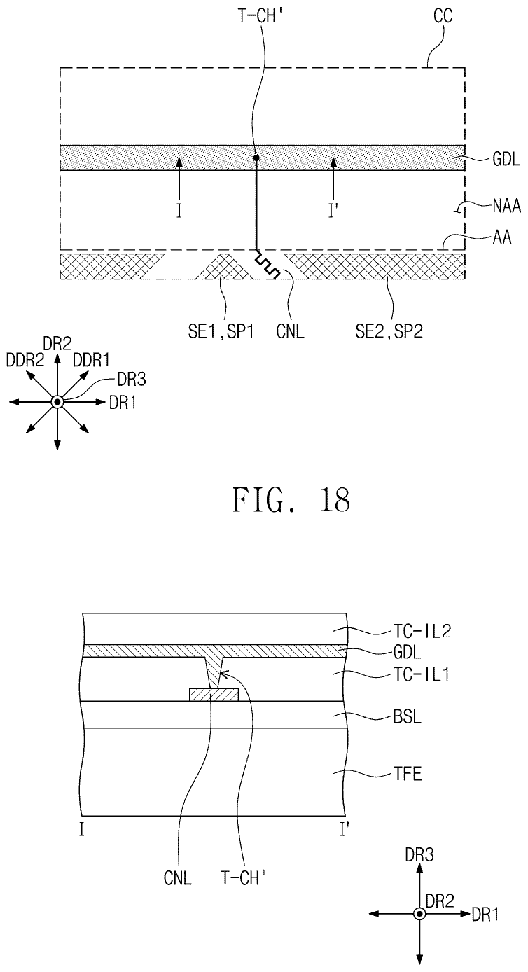

FIG. 18 is a cross-sectional view taken along line I-I′ illustrated in FIG. 17.

Referring to FIGS. 17 and 18, a connection line CNL may be disposed on the base layer BSL. A first insulating layer TC-IL1 may be disposed on the base layer BSL to cover the connection line CNL.

A guard line GDL may be disposed on the first insulating layer TC-IL1. Accordingly, the guard line GDL may be disposed in (or directly on) a same layer as the first and second sensing parts SP1 and SP2, the extension pattern EP, and the dummy electrode DE. The connection line CNL may be disposed in a layer that is different from a layer in which the guard line GDL is disposed. In an embodiment, for example, the connection line CNL may be disposed under the guard line GDL.

The guard line GDL may be connected to the connection line CNL through the contact hole T-CH′ defined in the first insulating layer TC-IL1. A second insulating layer TC-IL2 may be disposed on the guard line GDL.

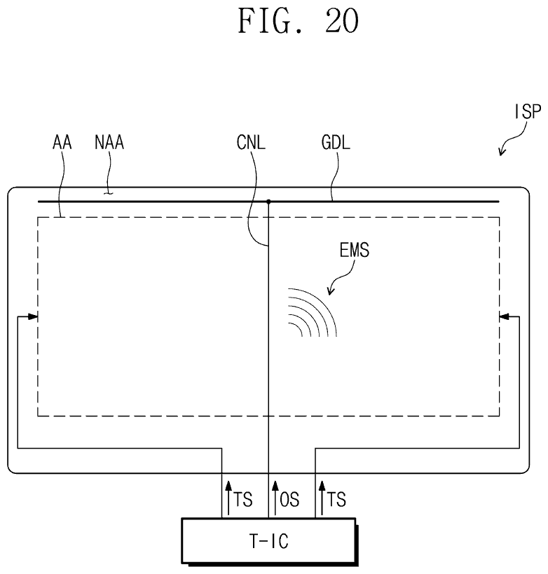

FIGS. 19A and 19B are views illustrating timings of a driving signal applied to first sensing electrodes illustrated in FIG. 9 and an offset signal applied to a connection line illustrated in FIG. 9, by way of example. FIG. 20 is a view illustrating a sensing controller for applying a driving signal and an offset signal to first sensing electrodes and a connection line illustrated in FIG. 9, by way of example.

By way of example, in FIG. 20, the sensing electrodes SE1 and SE2 disposed in the active area AA and the wiring lines TX1 to TXh, TX1′ to TXh′, and RX1 to RXk disposed in the non-active area NAA are omitted.

Referring to FIGS. 9, 19A, and 20, the input sensing part ISP may include a sensing controller T-IC. The sensing controller T-IC may generate a driving signal TS and an offset signal OS. The driving signal TS may be applied to the active area AA and the offset signal OS may be applied to the connection line CNL. A driving signal TS may be applied to the first sensing electrodes SE1 disposed in the active area AA. The offset signal OS may be applied to the guard line GDL through the connection line CNL.

A driving signal TS having a specific frequency may be applied to the first sensing electrodes SE1, and an offset signal OS having the specific frequency may be applied to the connection line CNL. The offset signal OS may have a phase that is opposite to that of the driving signal TS. The offset signal OS and the driving signal TS may have a same first amplitude AMP1.

An electromagnetic signal EMS may be generated in the input sensing part ISP by a driving signal TS having a specific frequency. The electromagnetic signals EMS may act as noise to other devices (electromagnetic interferences: EMIs) and may hinder the operations of other devices.

In an embodiment, the offset signal OS applied to the guard line GDL has a phase that is opposite to that of the driving signal TS applied to the active area AA, such that the electromagnetic signal EMS may be offset by the offset signal OS applied to the guard line GDL. In such an embodiment, by applying the offset signal OS having a phase opposite to that of the driving signal TS to the guard line GDL, the electromagnetic signal EMS generated from the input sensing part ISP may be attenuated by the offset signal OS.

Referring to FIGS. 9, 19B, and 20, in another embodiment, the offset signal OS may have a second amplitude AMP2 that is greater than the first amplitude AMP1 of the driving signal TS. An intensity of the electromagnetic signal EMS may be proportional to the number and extents of the first sensing electrodes SE1. Accordingly, the electromagnetic signal EMS may be generated to be greater. In an embodiment of the present disclosure, because the offset signal OS has a greater amplitude than that of the driving signal TS, the electromagnetic signal EMS generated largely may be further offset.

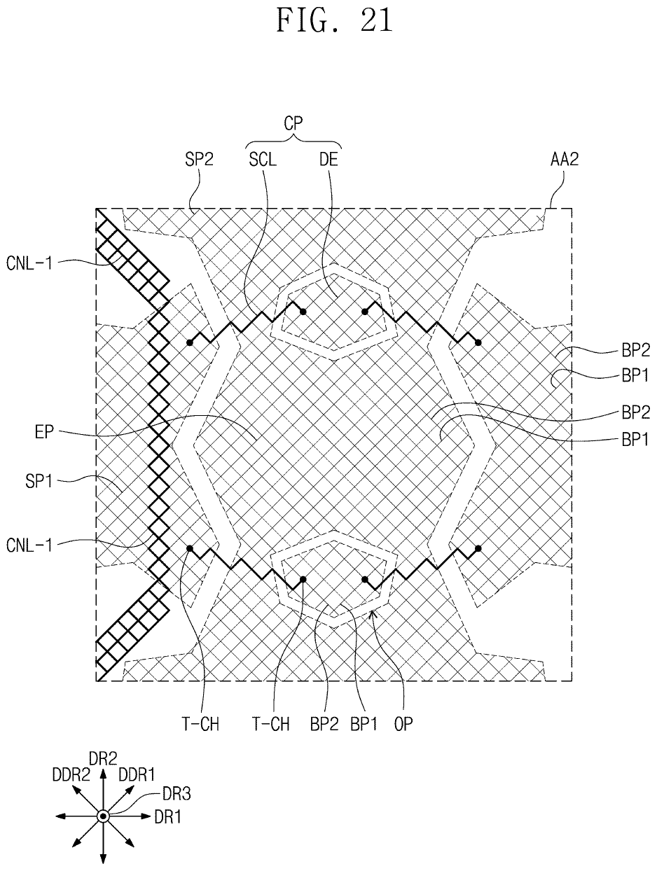

FIGS. 21 to 23 are views illustrating configurations of connection lines according to various embodiments of the present disclosure.

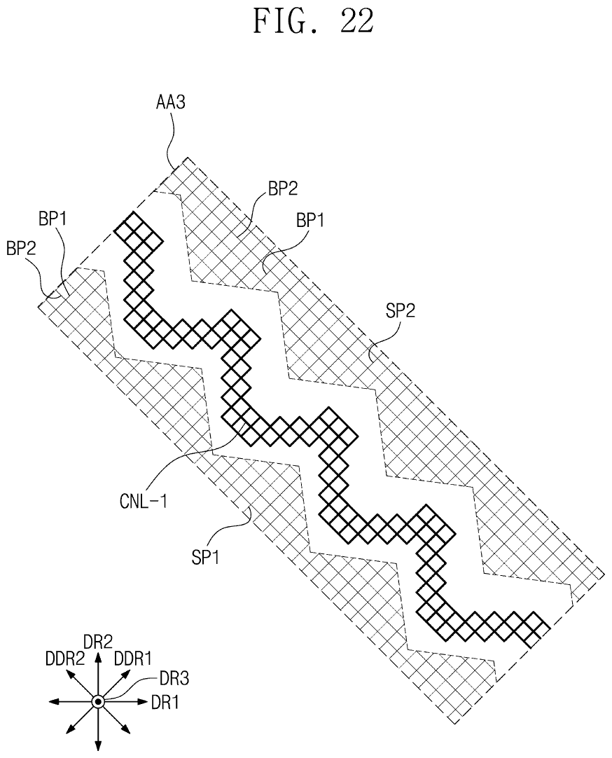

By way of example, FIGS. 21 and 22 are illustrated as enlarged views corresponding to FIGS. 12 and 16, and FIG. 23 is illustrated as a plan view corresponding to FIG. 9.

Referring to FIGS. 21 and 22, in an embodiment, a connection line CNL-1 may have a mesh shape in the active area AA. A resistance of the connection line CNL-1 having a mesh shape may be smaller than that of the connection line CNL that is a single line. In such an embodiment, the resistance of the connection line CNL-1 decreases, such that signal transmission characteristics of the connection line CNL-1 may be improved.

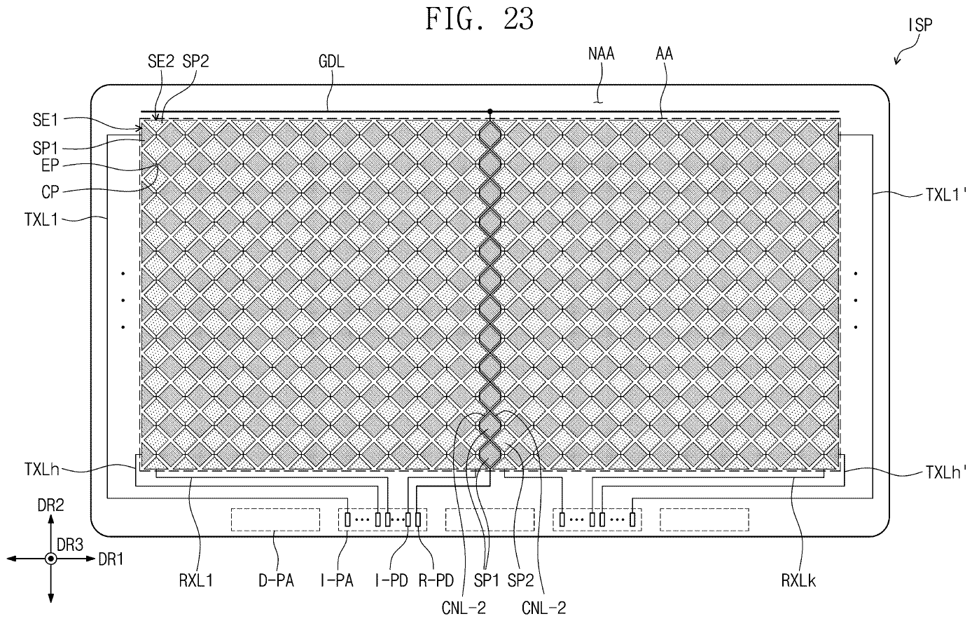

Referring to FIG. 23, a plurality of connection lines CNL-2 may be provided in the active area AA. In an embodiment, for example, two connection lines CNL-2 are illustrated, but the number of the connection lines CNL-2 is not limited thereto. The connection lines CNL-2 may extend between the first and second sensing parts SP1 and SP2.

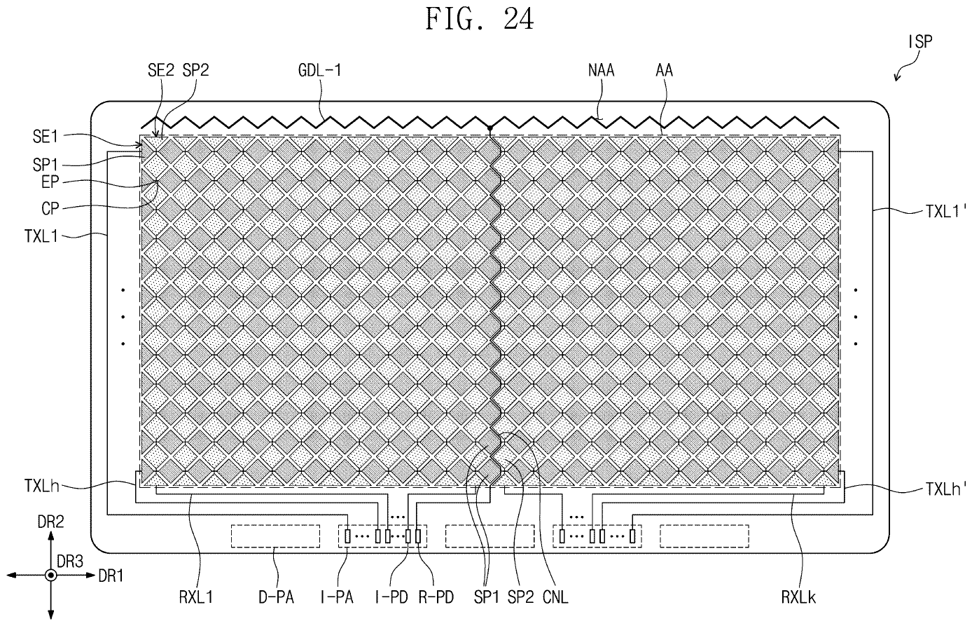

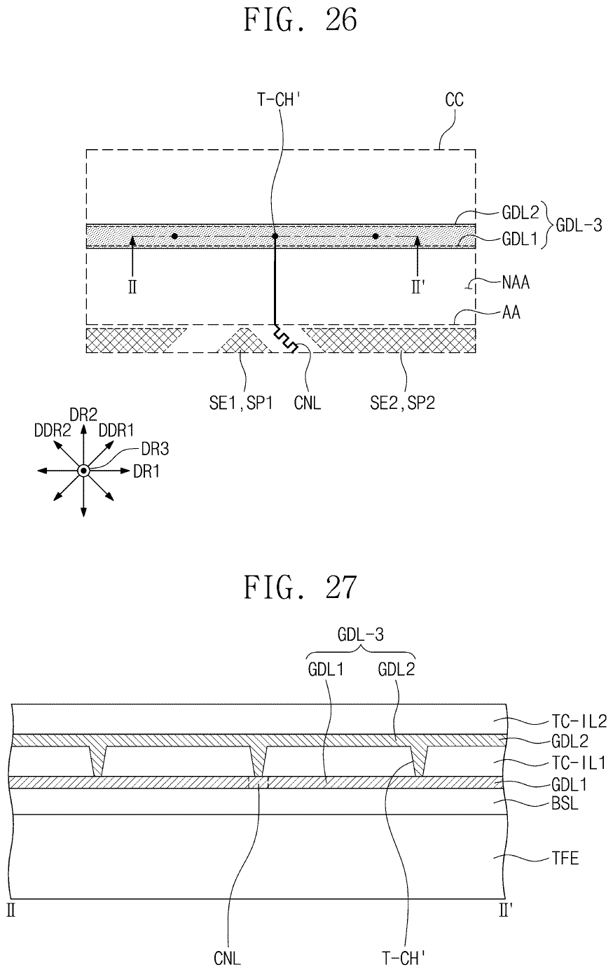

FIGS. 24 to 26 are views illustrating configurations of guard lines according to various embodiments of the present disclosure. FIG. 27 is a cross-sectional view taken along line II-II′ illustrated in FIG. 26.

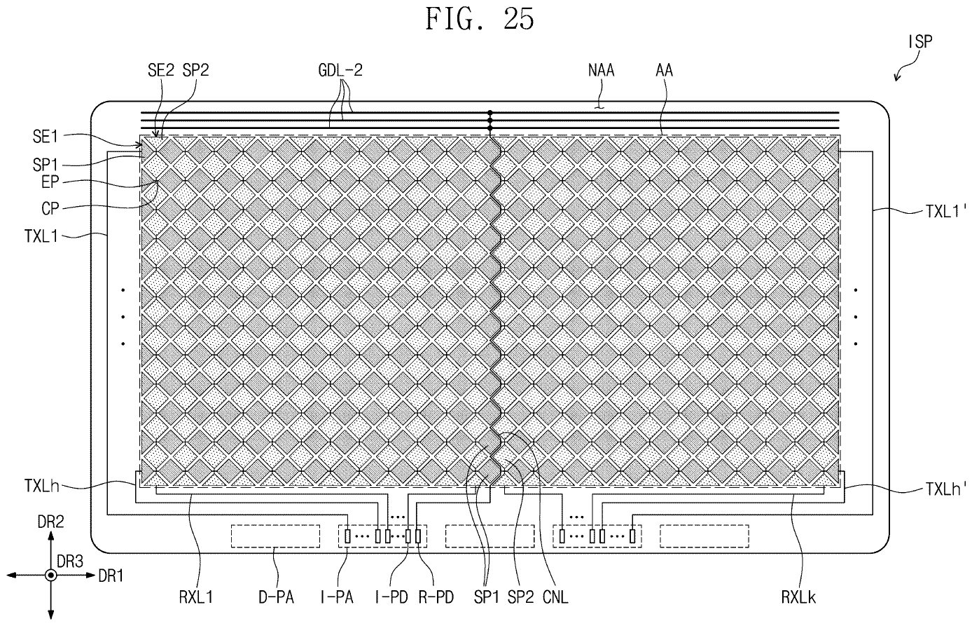

By way of example, FIGS. 24 and 25 are plan views corresponding to FIG. 9, and FIG. 26 is an enlarged view corresponding to FIG. 17.

Referring to FIG. 24, in an embodiment, a guard line GDL-1 may have a zigzag shape.

Referring to FIG. 25, in another embodiment, a plurality of guard lines GDL-2 may be disposed in a non-active area NAA. The connection line CNL may be connected to the guard lines GDL-2.

Referring to FIGS. 26 and 27, in an embodiment, a guard line GDL-3 may include a first guard line GDL1 and a second guard line GDL2 that is disposed on the first guard line GDL1. In a plan view, the first guard line GDL1 and the second guard line GDL2 may overlap each other as shown in FIG. 26. A first guard line GDL1 may be disposed on the base layer BSL. A first insulating layer TC-IL1 may be disposed on the first guard line GDL1. The connection line CNL may extend from the first guard line GDL1. The connection line CNL and the first guard line GDL1 may be integrally formed as a single unitary indivisible part.

A second guard line GDL2 may be disposed on the first insulating layer TC-IL1. A second insulating layer TC-IL2 may be disposed on the second guard line GDL2. The second guard line GDL2 may be connected to the first guard line GDL1 through the contact holes T-CH′ defined in the first insulating layer TC-IL1. The above-described offset signal OS may be applied to the first and second guard lines GDL1 and GDL2 through the connection line CNL.

According to an embodiment of the present disclosure, an offset signal having a phase that is opposite to that of the driving signal applied to the first sensing electrodes may be applied to the guard line through the connection line. Accordingly, an electromagnetic signal generated from the input sensing part may be attenuated by the offset signal.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An input sensing part comprising:
a first sensing electrode disposed in an active area, and extending in a first direction;
a second sensing electrode disposed in the active area, extending in a second direction crossing the first direction, and crossing the first sensing electrode while being insulated from the first sensing electrode;
a guard line disposed in a non-active area to be adjacent to an upper side of the active area when viewed on a plane; and
a connection line disposed in a non-active area to be adjacent to a lower side of the active area when viewed on the plane, extending toward the guard line via the active area, and connected to the guard line.

2. The input sensing part of claim 1, wherein the connection line is disposed under the guard line.

3. The input sensing part of claim 1, wherein the guard line extends in the first direction.

4. The input sensing part of claim 1, wherein the connection line extends via an area between the first sensing electrode and the second sensing electrode in the active area.

5. The input sensing part of claim 1, wherein the first sensing electrode includes:
two first sensing parts arranged in the first direction;
a plurality of sensor connection lines disposed between the two first sensing parts and connected to the two first sensing parts; and
a dummy electrode connected to the sensor connection lines, and
wherein the second sensing electrode includes:
two second sensing parts arranged in the second direction, and disposed adjacent to the two first sensing parts alternately with the two first sensing parts; and
an extension pattern disposed between the two second sensing parts, extending from one of the two second sensing parts to the other of one of the two second sensing parts, overlapping the connection line when viewed on the plane, wherein an opening, in which the dummy electrode is disposed, is defined in the extension pattern.

6. The input sensing part of claim 5, wherein the two first sensing parts, the two second sensing parts and the extension pattern are disposed in a same layer as each other, and are disposed in a layer different from a layer in which the sensor connection line is disposed.

7. The input sensing part of claim 6, wherein the connection line is disposed in a same layer as the sensor connection line.

8. The input sensing part of claim 6, wherein the guard line is disposed in the same layer as the two first sensing parts, the two second sensing parts and the extension pattern.

9. The input sensing part of claim 5, wherein the connection line extends via an area between one of the two first sensing parts and one of the two second sensing parts and an area between the one of the two first sensing parts and the other of the two second sensing parts.

10. The input sensing part of claim 9, wherein the connection line extends to cross a portion of the one of the two first sensing parts when viewed on the plane.

11. The input sensing part of claim 9, wherein the connection line extends to detour around the sensor connection lines not to overlap the sensor connection lines when viewed on the plane.

12. The input sensing part of claim 9, wherein the first sensing parts are disposed on the sensor connection lines,
wherein the first sensing parts are connected to the sensor connection lines through contact holes defined through insulating layers disposed between the first sensing parts and the sensor connection lines, and
wherein the connection line is adjacent to contact holes overlapping the one of the two first sensing parts.

13. The input sensing part of claim 1, wherein an offset signal applied to the guard line through the connection line has a phase opposite to a phase of a driving signal applied to the first sensing electrode.

14. The input sensing part of claim 1, wherein the connection line is defined as a single line.

15. The input sensing part of claim 1, wherein the connection line has a mesh shape.

16. The input sensing part of claim 1, wherein a plurality of guard lines is provided the active area, and a plurality of connection lines is provided in the active area.

17. The input sensing part of claim 1, wherein the guard line has a zigzag shape.

18. The input sensing part of claim 1, wherein the guard line includes:
a first guard line; and
a second guard line disposed on the first guard line and connected to the first guard line, and
wherein the connection line extends from the first guard line.

19. A display device comprising:
a display panel; and
an input sensing part disposed on the display panel,
wherein the input sensing part includes:
a first sensing electrode disposed in an active area, and extending in a first direction;
a second sensing electrode disposed in the active area, extending in a second direction crossing the first direction, and crossing the first sensing electrode while being insulated from the first sensing electrode;
a guard line disposed in a non-active area to be adjacent to an upper side of the active area when viewed on a plane; and
a connection line disposed in a non-active area to be adjacent to a lower side of the active area when viewed on the plane, extending toward the guard line via the active area, and connected to the guard line, and
wherein the connection line is disposed in a layer different from a layer in which the guard line is disposed.

20. An electronic device comprising:
a processor; and
a display device which receives an image signal from the processor, and provides a user with an image corresponding to the image signal,
wherein the display device includes:
a display panel; and
an input sensing part disposed on the display panel,
wherein the input sensing part includes:
a first sensing electrode disposed in an active area, and extending in a first direction;
a second sensing electrode disposed in the active area, extending in a second direction crossing the first direction, and crossing the first sensing electrode while being insulated from the first sensing electrode;
a guard line disposed in a non-active area to be adjacent to an upper side of the active area when viewed on a plane; and
a connection line disposed in a non-active area to be adjacent to a lower side of the active area when viewed on the plane, extending toward the guard line via the active area, and connected to the guard line, and
wherein the connection line extends via an area between the first sensing electrode and the second sensing electrode in the active area.
